(19) United States
(12) Patent Application Publication
(10) Pub. No.: US 2006/0186447 A1
(43) Pub. Date: Aug. 24, 2006

(54) Semiconductor memory and method for fabricating the same

(75) Inventor: Masahiro Saitoh, Fukuyama-shi (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 11/357,965

(22) Filed: Feb. 22, 2006

(30) Foreign Application Priority Data
Feb. 24, 2005 (JP) 2005-049263

(51) Int. Cl. H01L 29/94

(52) U.S. Cl. 257/296

(57) ABSTRACT

A semiconductor memory includes: a semiconductor substrate having a protrusion; a gate insulating film formed on an upper surface of the protrusion; a gate electrode formed on the gate insulating film; diffusion regions formed in portions of the substrate on both sides of the protrusion, the diffusion regions being disposed so as to reach edges of side surfaces of the protrusion; a channel region between the diffusion regions, the channel region being located below the gate electrode; and a charge-retaining portion formed on at least one side surface of the protrusion.

### CROSS-REFERENCE TO RELATED APPLICATION

This application is related to Japanese Patent Application No. 2005-049263 filed on Feb. 24, 2005, whose priory is claimed and the disclosure of which is incorporated by reference in its entirety.

### BACKGROUND OF THE INVENTION

1. Field of the Invention

The present invention relates to a semiconductor memory and a method for fabricating the same. More particularly, the present invention relates to a semiconductor memory which includes a field-effect transistor having a function of converting a change in charge amount to an electric current amount, and a method for fabricating the semiconductor memory.

2. Description of Related Art

Conventionally, in a semiconductor memory of a transistor type including a gate insulating film with charge retaining effect, scaling of the gate insulating film thickness has been difficult. This causes the short-channel effects to increase, making it difficult to shrink elements. In order to solve this problem, the applicant of the present application has proposed in Japanese Unexamined Patent Publication No. 2004-186663 a semiconductor memory which realizes two bit memory retention with a single transistor and can also be reduced in size.

This semiconductor memory is shown in FIG. 13. The memory includes a gate insulating film 52 formed on a semiconductor substrate 51, a gate electrode 53, charge-retaining portions 50A, 50B formed on opposite sidewalls of the gate insulating film 52 and the gate electrode 53, and first and second diffusion regions 57, 58 as source/drain formed in a surface of the substrate 51. Each of the charge-retaining portions 50A, 50B is configured so that a silicon nitride film 55 as a first insulator having a function of accumulating charges is sandwiched between silicon oxide films 54, 56 as second and third insulators having a function of preventing dissipation of charges retained in the first insulator. The semiconductor memory of this structure is constructed so that the amount of electric current flowing from the first diffusion region 57 to the second diffusion region 58 or from the second diffusion region 58 to the first diffusion region 57 is changed depending on the amount of charges retained in the first insulator 55.

In the semiconductor memory, since the charge-retaining portions 50A, 50B are formed independently of the gate insulating film 52, a memory function performed by the charge-retaining portions 50A, 50B and a transistor function performed by the gate insulating film 52 are separated. The two charge-retaining portions 50A, 50B formed on the opposite sides of the gate electrode 53 are physically separated by the gate electrode 53. This allows interference which occurs at a rewrite time to be effectively suppressed. Thus, a memory is capable of two-bit or greater storage and can easily be reduced in size.

In the semiconductor memory of the aforementioned Japanese Unexamined Patent Publication No. 2004-186663, the charge-retaining portions 50A, 50B are partially located below an interface between the gate insulating film 52 and a channel region 59. With this configuration, the efficiency of injecting charges to the charge-retaining portions 50A, 50B during a writing operation can be significantly improved, and still more, a writing rate can be improved. A distance D from the interface (a first surface) between the gate insulating film 52 and the channel region 59 to a surface (a second surface) including surfaces of the charge-retaining portions 50A, 50B is preferably in the range of 2 nm to 15 nm in order to realize the aforementioned effects.

Suppose, for example, the diffusion region 57 is a drain and the diffusion region 58 is a source. Currents that flow between the drain and source at the reading normally flow through an offset region 60A on the drain side, the channel region 59 and an offset region 60B on the source side. This memory, however, has an extra path existing on both sides of the channel region 59 by an amount equal to the distance D between the first and second surfaces, and thus, a read current path is longer in length.

Further, in this semiconductor memory, where W1 denotes the length of the offset regions and W2 denotes the width of the charge-retaining portions in the form of sidewall spacers as shown in FIG. 13, the relationship W2−W1>10 nm is preferably satisfied in order to realize stable high-speed reading. This means that where W1 is set to 60 nm, for example, the film structure of each charge-retaining portion composed of the first insulator for retaining charges and the second and third insulators for preventing dissipation of the charges is restricted such that W2>70 nm.

### SUMMARY OF THE INVENTION

In view of the aforementioned problems, the present invention provides, in one aspect, a semiconductor memory that suppresses an increase in length of a read current path from a drain to a source even when charge-retaining portions are located below an interface between a gate insulating film and a channel.

The present invention provides, in another aspect, a semiconductor memory in which the length of offset regions can be set without the film thickness of charge-retaining portions being restricted.

An aspect of the present invention provides a semiconductor memory comprising: a semiconductor substrate having a protrusion; a gate insulating film formed on an upper surface of the protrusion; a gate electrode formed on the gate insulating film; diffusion regions formed in portions of the substrate on both sides of the protrusion, the diffusion regions being disposed so as to reach edges of side surfaces of the protrusion; a channel region between the diffusion regions, the channel region being located below the gate electrode; and a charge-retaining portion formed on at least one side surface of the protrusion.

According to another aspect of the invention, provided is a method for fabricating a semiconductor memory comprising the steps of: forming a gate insulating film on a semiconductor substrate; forming a film, as a material of a gate electrode, on the gate insulating film, the material film being made of a material greater in thermal oxidation rate than the substrate; forming the gate electrode by processing the material film; forming a protrusion on a surface of the substrate by processing the substrate; forming diffusion regions in the surface of the substrate; and forming charge-retaining layers on side surfaces of the protrusion.

According to still another aspect of the invention, there is provided a method for fabricating a semiconductor memory comprising the steps of: forming a gate insulating film on a semiconductor substrate; forming a film, as a material of a gate electrode, on the gate insulating film, the material film being made of a material greater in thermal oxidation rate than the substrate; forming the gate electrode by processing the material film; forming a protrusion on a surface of the substrate by processing the substrate; forming charge-retaining layers on side surfaces of the protrusion; and forming diffusion regions in portions of the substrate below the charge-retaining layers.

### BRIEF DESCRIPTION OF THE DRAWINGS

The present invention will become more fully understood from the detailed description given hereinbelow and the accompanying drawings which are given by way of illustration only, and thus are not limitative of the present invention and wherein:

FIG. 1 is a schematic cross-sectional view of essential parts of a semiconductor memory according to first and second embodiments of the invention;

FIG. 2 is a schematic plan layout view of essential parts of the semiconductor memory of the first embodiment;

FIG. 3A is a plan layout view illustrating only active regions and isolation regions of FIG. 2;

FIG. 3B is a plan layout view illustrating a gate electrode and diffusion regions of FIG. 2, the gate electrode outlined in a heavy line and diffusion regions shaded with oblique lines;

FIG. 3C is a plan layout view illustrating only the gate electrode and charge-retaining portions of FIG. 2;

FIG. 4 is a schematic cross-sectional view of essential parts of the semiconductor memory of the first embodiment, for explanation of a writing operation;

FIG. 5A to FIG. 5D are schematic cross-sectional views showing in order a series of steps for fabricating the semiconductor memory of the first embodiment;

FIG. 6A to FIG. 6D are schematic cross-sectional views showing in order a series of steps for fabricating the semiconductor memory of the second embodiment;

FIG. 7 is a schematic cross-sectional view of essential parts of a semiconductor memory according to a third embodiment of the invention;

FIG. 8 is a schematic cross-sectional view of essential parts of a semiconductor memory according to a fourth embodiment of the invention;

FIG. 9A to FIG. 9C are schematic cross-sectional views showing in order a series of steps for fabricating the semiconductor memory of the fourth embodiment;

FIG. 10 is a schematic cross-sectional view of essential parts of a semiconductor memory according to a fifth embodiment of the invention;

FIG. 11 is a schematic cross-sectional view of essential parts of a semiconductor memory according to a sixth embodiment of the invention;

FIG. 12A and FIG. 12B are schematic cross-sectional views showing in order a series of steps for fabricating a semiconductor substrate having a protrusion according to an embodiment of the invention; and

FIG. 13 is a schematic cross-sectional view of a conventional semiconductor memory.

### DESCRIPTION OF THE PREFERRED EMBODIMENTS

In accordance with the present invention, a semiconductor memory comprises: a semiconductor substrate having a protrusion; a gate insulating film formed on an upper surface of the protrusion; a gate electrode formed on the gate insulating film; diffusion regions formed in portions of the substrate on both sides of the protrusion, the diffusion regions being disposed so as to reach edges of side surfaces of the protrusion; a channel region between the diffusion regions, the channel region being located below the gate electrode; and a charge-retaining portion formed on at least one side surface of the protrusion.

In the semiconductor memory of the present invention, the diffusion regions may be formed so as to extend below opposite edges of the gate electrode.

Further, the memory may further include an isolation region for dividing the protrusion into a plurality of active regions, and an area of the substrate below the charge-retaining portion within the active region may be a part of the diffusion regions.

According to the present invention, an amount of electric current that flows from one of the diffusion regions to the other diffusion region is changed depending on an amount of charges retained in the charge-retaining portion.

In the memory of the invention, the charge-retaining potion preferably includes a first insulator having a function of retaining charges, and second and third insulators having a function of preventing dissipation of the charges retained in the first insulator. Preferably, the first insulator is sandwiched between the second and third insulators.

The first insulator may be silicon nitride, and the second and third insulators may be silicon oxide.

The second insulator preferably is in the form of a film and is interposed between the substrate and the first insulator, and the second insulator on the substrate preferably has a thickness of 1.5 nm to 15 nm.

The first insulator above the substrate preferably has a thickness of 2 nm to 15 nm.

Further, the second insulator preferably is in the form of a film and is interposed partially between the first insulator and the substrate and partially between the first insulator and a sidewall of the gate electrode, the second insulator on the sidewall of the gate electrode preferably is greater in thickness than the second insulator on the side surface of the protrusion.

According to the present invention, the second insulator on the side surface of the protrusion may be smaller in thickness than the gate insulating film, and may have a thickness of 0.8 nm or greater.

Alternatively, the second insulator on the side surface of the protrusion may be greater in thickness than the gate insulating film, and may have a thickness of 20 nm or smaller.

The present invention also provides a method for fabricating a semiconductor memory comprising the steps of: forming a gate insulating film on a semiconductor substrate; forming a film, as a material of a gate electrode, on the gate insulating film, the material film being made of a material greater in thermal oxidation rate than the substrate; forming the gate electrode by processing the material film; forming a protrusion on a surface of the substrate by processing the substrate; forming diffusion regions in the surface of the substrate; and forming charge-retaining layers on side surfaces of the protrusion.

Furthermore, the present invention provides a method for fabricating a semiconductor memory comprising the steps of: forming a gate insulating film on a semiconductor substrate; forming a film, as a material of a gate electrode, on the gate insulating film, the material film being made of a material greater in thermal oxidation rate than the substrate; forming the gate electrode by processing the material film; forming a protrusion on a surface of the substrate by processing the substrate; forming charge-retaining layers on side surfaces of the protrusion; and forming diffusion regions in portions of the substrate below the charge-retaining layers.

In the memory of invention, the semiconductor substrate having the protrusion is used, and the diffusion regions are formed in the portions of the substrate on both sides of the protrusion. The diffusion regions are configured so as to reach at least the edges of side surfaces of the protrusion. Alternatively, the semiconductor memory of the invention has a structure in which, on the active region, all of the area, located below the charge-retaining portion, of the substrate is defined as a part of the diffusion regions serving as source/drain. In other words, only the side surfaces of the protrusion below the sidewalls of the gate electrode are defined as offset regions, so that there is no extra path added to a read current path from the drain to the source. This allows the memory to have a greater current amount than a memory of a conventional structure does while maintaining a high charge injection efficiency at a writing operation. As a result, an access time for reading can be reduced.

Furthermore, the charge-retaining portion is located above at least one of the diffusion regions. With this configuration, the length (W1) of the offset regions in the direction of the substrate depth can be freely set irrespective of the width (W2) of the sidewall spacers as the charge-retaining portions. Therefore, there is a higher flexibility in determining the film structure of the charge-retaining portion composed of the first insulator for retaining charges and the second and third insulators for preventing dissipation of the charges. Further, the area of the transistor is not limited by the offset regions, making it possible to shrink a memory cell transistor.

With reference to the attached drawings, the semiconductor memory of the present invention will hereinafter be described in detail by way of embodiments thereof.

### First Embodiment

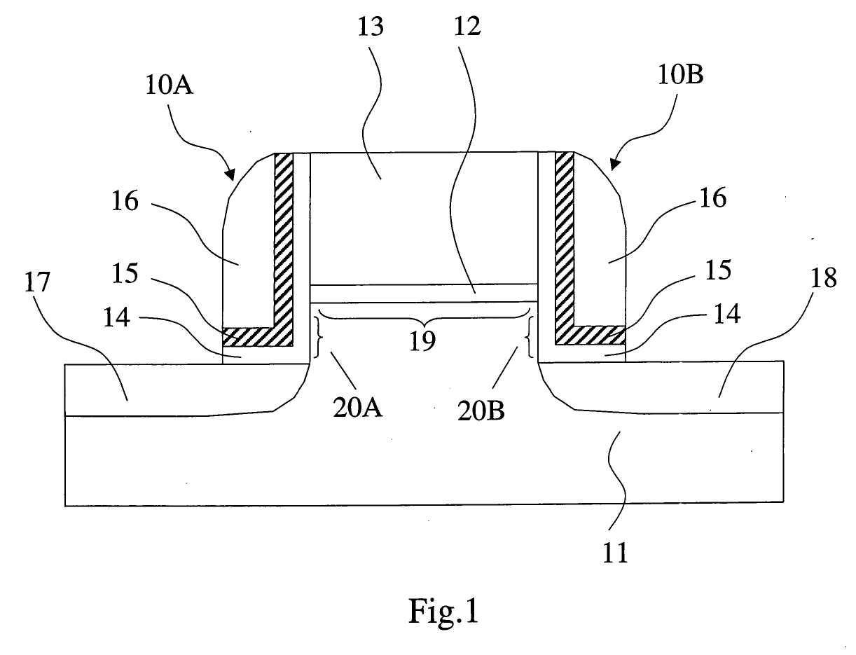

FIG. 1 is a view of a memory cell that makes up a semiconductor memory according to a first embodiment of the invention. The memory cell is a nonvolatile memory cell that can realize two-bit storage. The memory cell has a single gate electrode 13 of about the same in gate length as an usual transistor, for example, of about 0.025 μm to 0.5 μm in gate length formed, via a gate insulating film 12, on an upper surface of a protrusion provided on a surface of a semiconductor substrate 11. The memory cell has charge-retaining portions 10A, 10B in the form of sidewall spacers formed on opposite sidewalls of the gate insulating film 12 and the gate electrode 13. Each of the charge-retaining portions 10A, 10B, in one example, includes a silicon nitride film 15 as a first insulator having a function of retaining charges and silicon oxide films 14, 16 as second and third insulators having a function of preventing dissipation of the charges retained by the first insulator. The silicon nitride film 15 is sandwiched between the silicon oxide films 14 and 16. The charge-retaining portions 10A, 10B are partially located below the upper surface of the protrusion. The substrate 11 has first and second diffusion regions 17, 18 serving as source/drain formed in portions of the substrate on both sides of the protrusion. The charge-retaining portions 10A, 10B are formed above the first and second diffusion regions 17, 18. This means that according to the constitution of the present invention, the first and second diffusion regions 17, 18, which are provided below the protrusion on both sides thereof, sufficiently reach edges of side surfaces of the protrusion. Thus, one of the characteristics of the present invention is that it does not have offset regions located below the protrusion on both sides thereof as in the aforementioned Japanese Unexamined Patent Publication No. 2004-186663.

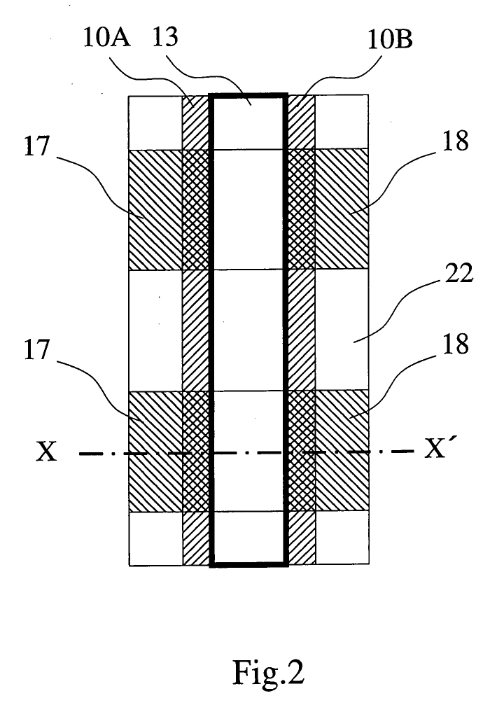

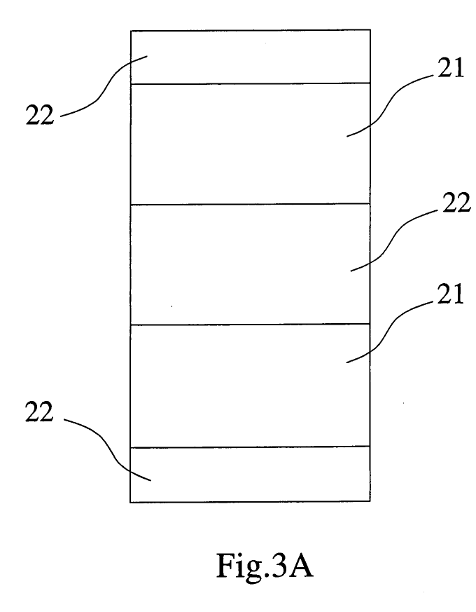

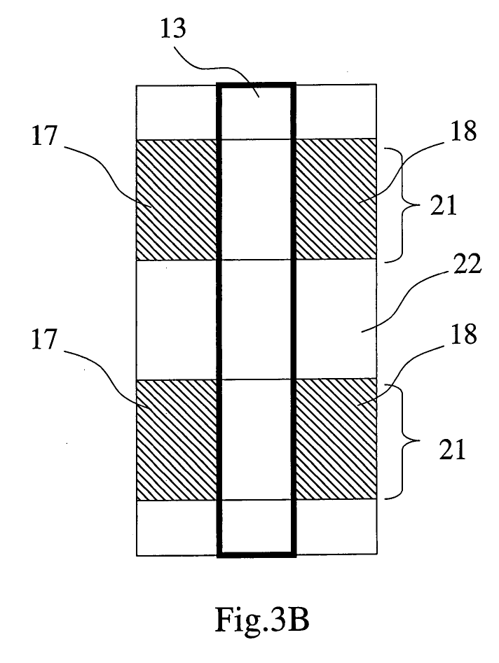

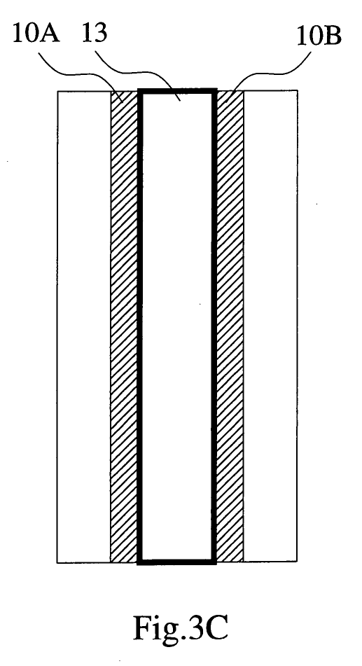

The positional relationship among the diffusion regions 17, 18 and the charge-retaining portions 10A, 10B is further explained below with reference to plan layout views of FIG. 2 and FIG. 3A to FIG. 3C. FIG. 2 is a plan layout view of the semiconductor memory of the first embodiment. FIG. 3A to FIG. 3C are views showing only a few components of FIG. 2 so that a portion of the memory in which the components are overlapped is easier to understand. FIG. 3A shows only active regions 21 and isolation regions 22 of FIG. 2, FIG. 3B shows the gate electrode 13 in a heavy line and the first and second diffusion regions 17, 18 in oblique lines (areas shaded with oblique lines from the upper left to the lower right). The first diffusion regions 17 of adjacent memory cells as well as the second diffusion regions 18 of the adjacent memory cells are separated by the isolation regions 22. FIG. 3C shows only the gate electrode in a heavy line and the charge-retaining portions 10A, 10B, which are in the form of sidewall spacers formed on the sidewalls of the gate electrode 13, in oblique lines (areas shaded with oblique lines from the upper right to the lower left).

The semiconductor memory of the first embodiment is characterized by regions of the substrate 11 located below the protrusion on both sides thereof within the active region and by the charge-retaining portions 10A, 10B. In FIG. 2, regions under the charge-retaining portions 10A, 10B are indicated by a check pattern in which oblique lines are crossed. These regions are configured to be a part of the first and second diffusion regions 17, 18. The cross-sectional view of the memory cell shown in FIG. 1 is taken along a dotted line X-X′ in FIG. 2. In the first embodiment, the charge-retaining portions 10A, 10B extend over the active regions 21 and the isolation regions 22. However, the charge-retaining portions 10A, 10B, may only be formed above the first and second diffusion regions 17, 18 within the active regions.

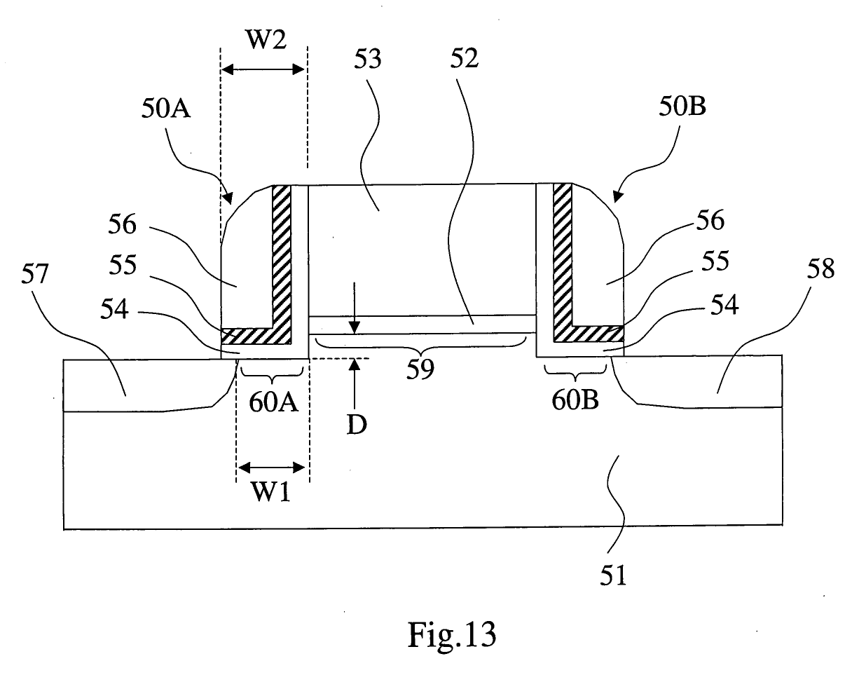

Now, writing of the semiconductor memory of the first embodiment is described below. Writing into the memory cell is performed by injecting electrons accelerated by a drain field into the charge-retaining portions in completely the same manner as in a conventional semiconductor memory shown in FIG. 13.

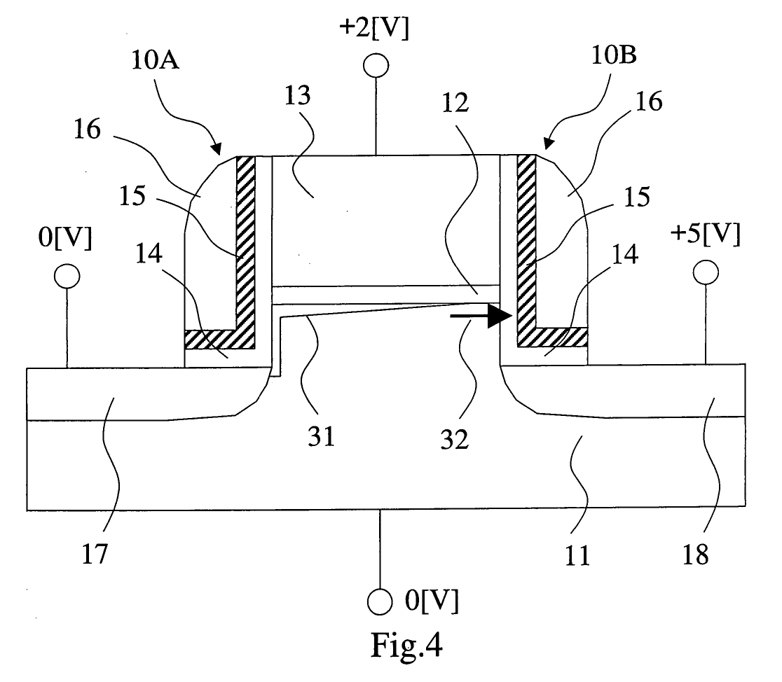

As shown in FIG. 4, the first and second diffusion regions 17, 18 are defined as source and drain electrodes, respectively, in order to inject electrons (write) into the charge-retaining portion 10B. For example, 0 V is applied to the first diffusion region 17 and the substrate 11, +5 V is applied to the second diffusion region 18, and +2 V is applied to the gate electrode 13. Under such voltage parameters, an inversion layer 31 extends from the first diffusion region 17 (source electrode) but does not reach the second diffusion region 18 (drain electrode), and a pinch-off point appears. Electrons are accelerated from the pinch-off point to the second diffusion region 18 (drain electrode) by the drain field. With this acceleration, the electrons are injected into the charge-retaining portion 10B (more precisely, a silicon nitride film 15 in the charge-retaining portion 10B). Writing of the memory is thus carried out.

Since there are no electrons accelerated by the drain field in the vicinity of the charge-retaining portion 10A, writing into the charge-retaining portion 10A is not performed. The write voltages are not limited to those mentioned above, and for example, 0 V may be applied to the first diffusion region 17 and the substrate, +10 V may be applied to the second diffusion region 18, and +5V may be applied to the gate electrode 13. Under such voltage parameters as well, hot electrons are injected into the charge-retaining portion 10B to carry out the writing.

In the semiconductor memory of the first embodiment, the charge-retaining portions 10A, 10B are partially located at a level below an interface between the substrate 11 and a channel region 19 as in the conventional semiconductor memory shown in FIG. 13. For this reason, electrons move in the direction shown by an arrow 32 in FIG. 4. Most of the electrons are injected into the silicon nitride film 15 in the second charge-retaining portion 10B. In other words, the electrons accelerated from the pinch-off point mostly possess great momentum in the direction of the arrow 32, and therefore, the electrons pass through the silicon oxide film 14 and are injected into the silicon nitride film 15. As a result of this, the number of injected electrons dramatically increases. This significantly improves the writing efficiency, and further improves the writing speed dramatically. Furthermore, a writing operation can be carried out even when a write current is small. Accordingly, power consumption at writing the semiconductor memory can be reduced.

In order to inject electrons (write) into the charge-retaining portion 10A, the source/drain regions are interchanged so that the first diffusion region 17 serves as the drain electrode and the second diffusion region 18 serves as the source electrode. Then, 0 V is applied to the second diffusion region 18 and the substrate 11, +5 V is applied to the first diffusion region 17, and +2 V is applied to the gate electrode 13.

Referring to FIG. 1, the principle of reading operation of the semiconductor memory according to the first embodiment is now explained. When reading information stored in the charge-retaining portion 10B, the first diffusion region 17 serves as the drain electrode and the second diffusion region 18 serves as the source electrode. A transistor is operated in a saturated region. For example, 0 V is applied to the second diffusion region 18 and the substrate 11, +2 V is applied to the first diffusion region 17, and +1 V is applied to the gate electrode 13. Under such voltage parameters, a drain current easily flows when electrons are not accumulated in the charge-retaining portion 10B. On the other hand, when electrons are accumulated in the charge-retaining portion 10B, an inversion layer is not easily formed in the vicinity of the charge-retaining portion 10B, rendering it difficult for a drain current to flow. Therefore, by detecting drain current, information stored in the charge-retaining portion 10B can be read. The presence/absence of charge accumulation in the charge-retaining portion 10A does not affect the drain current since the channel near the drain is pinched off.

When reading information stored in the charge-retaining portion 10A, the source/drain regions are interchanged so that the first diffusion region 17 serves as the source electrode and the second diffusion region 18 serves as the drain electrode.

The semiconductor memory of the first embodiment has offset regions 20A, 20B, which are substantially vertical to the surface of the substrate, formed under opposite edges of the gate electrode 13. Therefore, when reading information stored in the charge-retaining portion 10B, a path of current that flows between the drain (first diffusion region 17) and the source (second diffusion region 18) consists of the drain-side offset region 20A, the channel region 19 and the source-side offset region 20B.

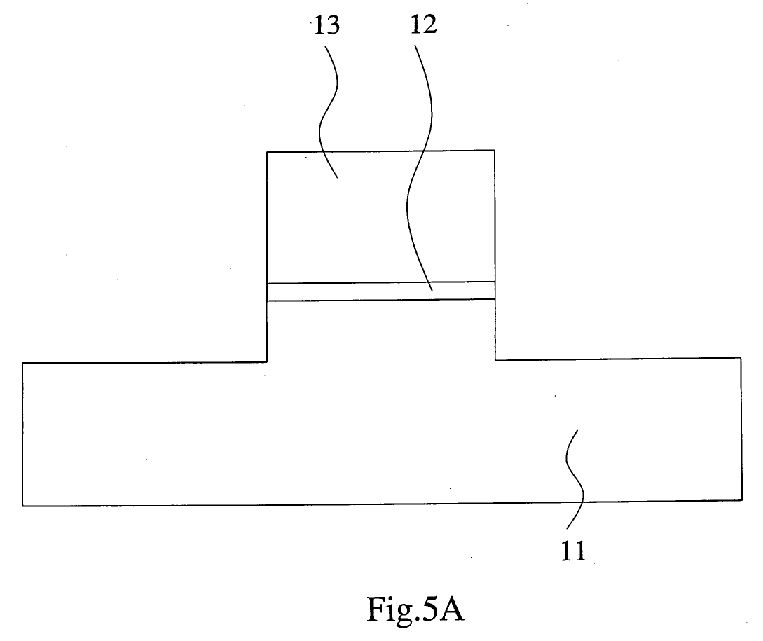

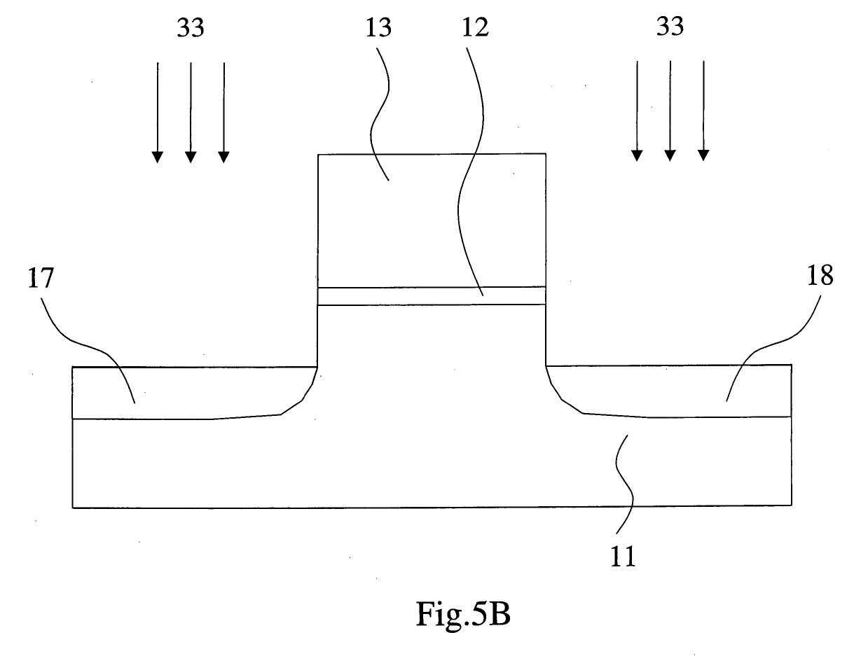

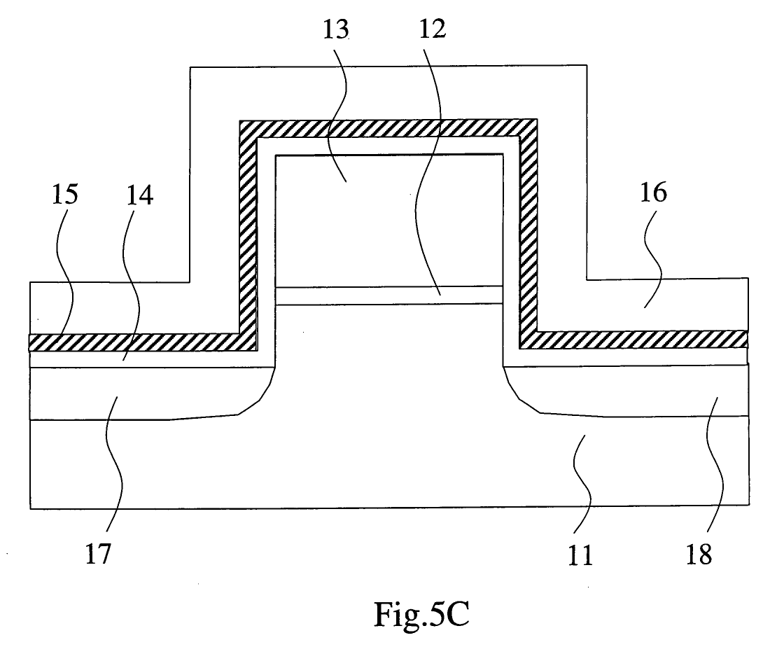

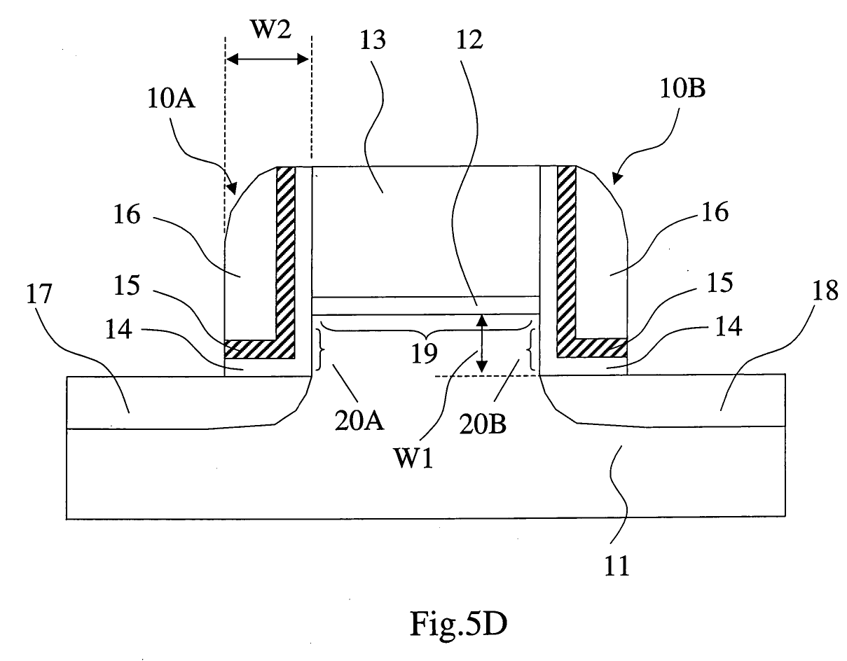

The semiconductor memory of the first embodiment can be fabricated by the following steps. A fabrication method of the semiconductor memory of the first embodiment is now explained with reference to FIG. 5A to FIG. 5D. First, on the semiconductor substrate 11 having isolation regions (not shown) formed therein, the gate insulating film 12 made of a silicon oxide nitride film having a thickness of, for example, about 1 nm to 6 nm is formed. On the gate insulating film 12, a gate electrode material film, made of polysilicon or a multilayer film of polysilicon and a refractory metal silicide or of polysilicon and a metal, having a thickness of about 50 nm to 400 nm is formed. The gate electrode material film is patterned to a desired shape by, for example, anisotropic etching. Thus, the gate electrode 13 is formed.

Then, the gate insulating film 12 made of the silicon oxide nitride film is etched. Subsequently, the substrate 11 is patterned by, for example, anisotropic etching so that it has a depth of about 15 nm to 100 nm. By this step, the substrate 11 having the protrusion is formed with the upper surface thereof being located below the gate electrode 13 as shown in FIG. 5A. In the portions of the substrate on both sides of the protrusion, the diffusions regions 17, 18 are formed at a level below the upper surface of the protrusion.

The gate insulating film 12 and the gate electrode 13 can be formed by the steps similar to those adopted in a standard logic process. Therefore, a material that is used according to the scaling law in a logic process at the generation may be used, and materials for the gate insulating film and the gate electrode are not limited to those mentioned above.

Next, as shown in FIG. 5B, the resulting substrate 11 is subjected to ion implantation (shown by an arrow 33 in the figure) to form the first and second diffusion regions 17, 18 serving as the source/drain. The ion implantation is performed so that ions are not implanted into portions of the substrate 11 (side surfaces of the protrusion), which serve as offset regions, located below the opposite edges of the gate electrode 13. In other words, ions are preferably implanted at 0 degree, that is, in the direction of the normal to the substrate. By such a step, the diffusion regions can be configured to be located on both sides of the protrusion such that the diffusion regions reach the edges of the side surfaces of the protrusion.

Subsequently, as shown in FIG. 5C, the silicon oxide film 14, for example, having a thickness of 1.5 nm to 15 nm, more preferably a thickness of 5 nm to 12 nm is deposited by a CVD (Chemical Vapor Deposition) method. The silicon oxide film 14 may be formed by thermal oxidation.

Then, on the entire surface of the silicon oxide film 14, the silicon nitride film 15, for example, having a thickness of 2 nm to 15 nm, more preferably a thickness of 3 nm to 7 nm is deposited by a CVD method. Further, on the entire surface of the silicon nitride film 15, the silicon oxide film 16 having a thickness of 20 nm to 150 nm is deposited by a CVD method.

The silicon oxide films 16, 14 and the silicon nitride film 15 are then etched back by anisotropic etching. By this step, the charge-retaining portions 10A, 10B suitable for storage as shown in FIG. 5D are formed in the form of sidewall spacers on the opposite sidewalls of the gate electrode 13. As in the conventional semiconductor memory of FIG. 13, W1 denotes the length of the offset regions 20A, 20B, and W2 denotes the width of the sidewall spacers.

The semiconductor memory according to the first embodiment of the invention fabricated in the above manner has the first and second diffusion regions 17, 18 serving as the source/drain formed prior to the formation of the charge-retaining portions 10A, 10B serving as the sidewall spacers. Therefore, the length W1 of the offset regions 20A, 20B is not dependent upon the sidewall width W2 and is determined by the distance between the upper surface of the protrusion and the surface of the substrate 11 on both sides of the protrusion. In other words, the length W1 is determined by the etching depth of the substrate 11 in the step shown in FIG. 5A.

In the semiconductor memory of the first embodiment, the thickness of the silicon oxide film 14 as the second insulator is set to 1.5 nm to 15 nm for the following reasons. Where the silicon oxide film 14 has a thickness of 1.5 nm or smaller, charges accumulated in the silicon nitride film 15 serving as the first insulator is apt to escape through the silicon oxide film 14, and thus the retention time significantly decreases. On the other hand, where the thickness of the silicon oxide film 14 is 15 nm or greater, the efficiency of injecting charges to the silicon nitride film 15 is impaired, and thus, an increase in write time becomes crucial. The silicon oxide film 14 as the second insulator thus preferably has a thickness of 1.5 nm to 15 nm so that a sufficient retention time and high-speed rewriting can both be realized.

Further, in the semiconductor memory of the first embodiment, the thickness of the silicon nitride film 15 as the first insulator is set to 2 nm to 15 nm for the following reasons. Where the thickness of the silicon nitride film 15 is 2 nm or smaller, the charge trap density in the silicon nitride film 15 becomes insufficient, resulting in an insufficient threshold value change (or read current change) of the memory cell. Further, there is a problem that the thickness of the silicon nitride film 15 varies among the cells or wafers. On the other hand, where the thickness of the silicon nitride film 15 is 15 nm or greater, it is difficult to uniformly inject charges into the silicon nitride film at the time of rewriting or it requires more time to do so. Where charges are not uniformly injected into the silicon nitride film, the charges move inside the silicon nitride film during the memory retention, and the threshold value change (or read current change) becomes a problem. The silicon nitride film 15 serving as the first insulator thus preferably has a thickness of 2 nm to 15 nm so that the memory cell has sufficient reliability.

### Second Embodiment

A memory cell that makes up a semiconductor memory according to a second embodiment of the invention has the same structure as that of the semiconductor memory shown in FIG. 1. However, in a fabrication method of the memory of the second embodiment, diffusion regions are formed in a manner different from that used in the method of the first embodiment. The fabrication method according to the second embodiment will be described below.

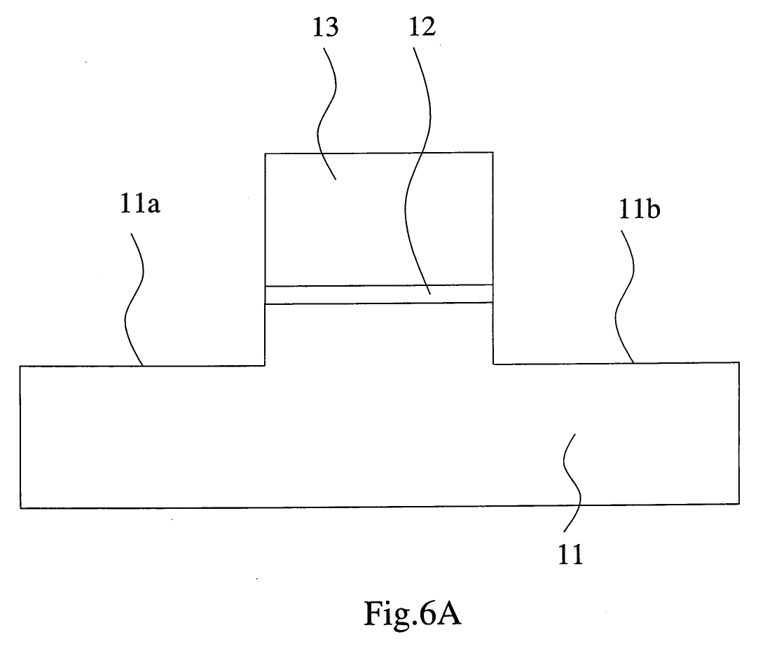

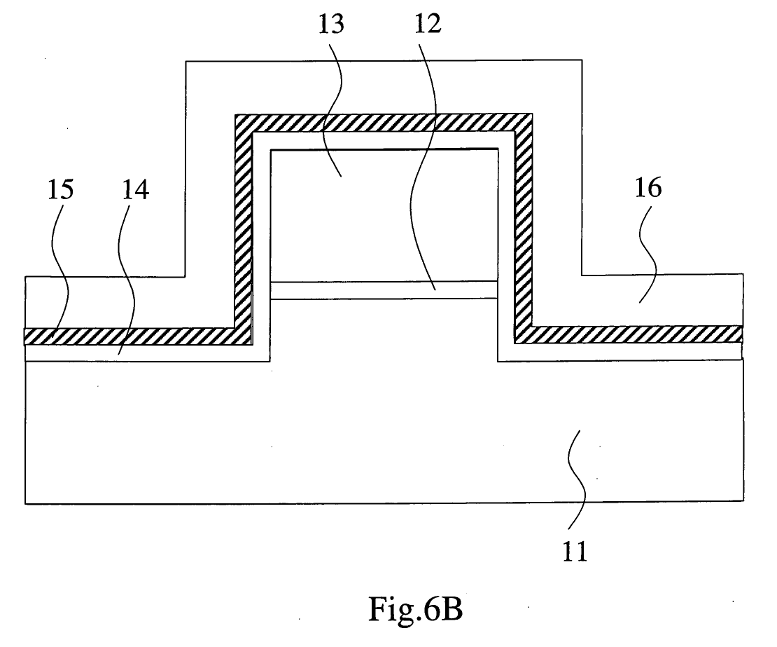

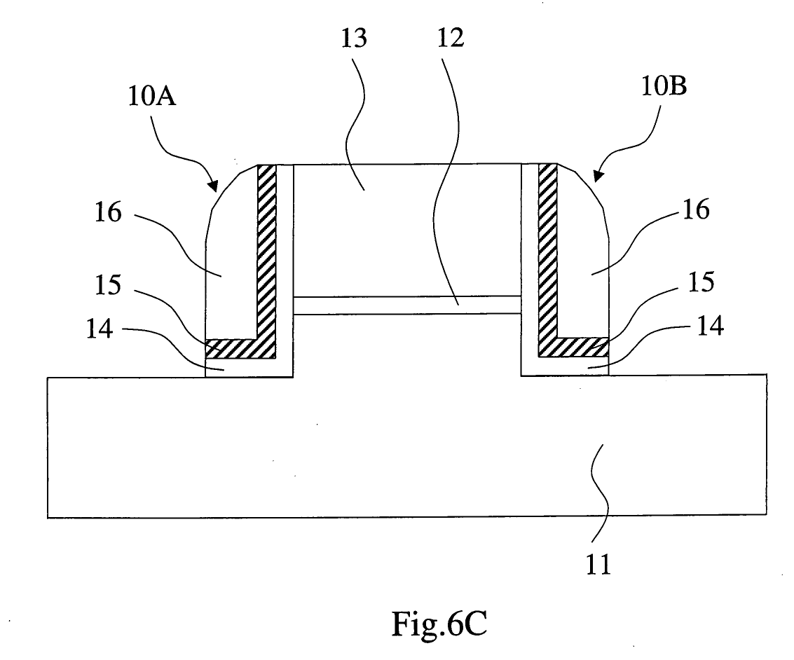

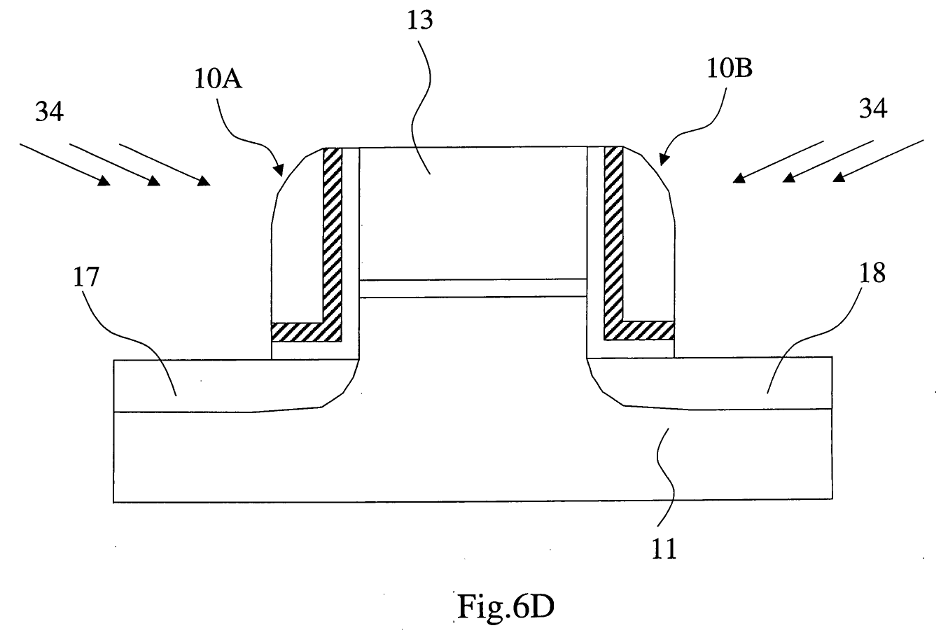

The memory cell of the second embodiment can be fabricated by the following steps. First, as shown in FIG. 6A, surfaces 11a, 11b of a substrate 11 are formed on both sides of a protrusion so as to be at a level lower than the upper surface of the protrusion below a gate electrode 13, in completely the same manner as the first embodiment.

As shown in FIG. 6B, a silicon oxide film 14, for example, having a thickness of 1.5 nm to 15 nm, more preferably a thickness of 5 nm to 12 nm is deposited by a CVD (Chemical Vapor Deposition) method. The silicon oxide film 14 may be formed by thermal oxidation. Then, on the entire surface of the silicon oxide film 14, a silicon nitride film 15, for example, having a thickness of 2 nm to 15 nm, more preferably a thickness of 3 nm to 7 nm is deposited by a CVD method. Further, on the entire surface of the silicon nitride film 15, a silicon oxide film 16 having a thickness of 20 nm to 150 nm is deposited by a CVD method.

Subsequently, the silicon oxide films 16, 14 and the silicon nitride film 15 are etched back by anisotropic etching. By this step, charge-retaining portions 10A, 10B suitable for storage as shown in FIG. 6C are formed in the form of sidewall spacers on sidewalls of the gate electrode 13.

Next, ion implantation is performed (shown by an arrow 34 in FIG. 6D) to form first and second diffusion regions 17, 18 serving as source/drain. The ions need to be implanted at a certain angle so that a greatest possible amount of ions can be implanted into portions of the substrate 11 located on both sides of the protrusion and under the charge-retaining portions 10A, 10B. In this embodiment, ions are implanted from both sides of the gate electrode 13 at an angle of about 60 degrees relative to the direction of the normal to the substrate 11. Further, as shown in FIG. 6D, the first and second diffusion regions 17, 18 are formed, by thermal diffusion, in the portions of the substrate 11 under the charge-retaining portions 10A, 10B.

Writing and reading of the semiconductor memory of the second embodiment can be done in the same manner as in the first embodiment.

### Third Embodiment

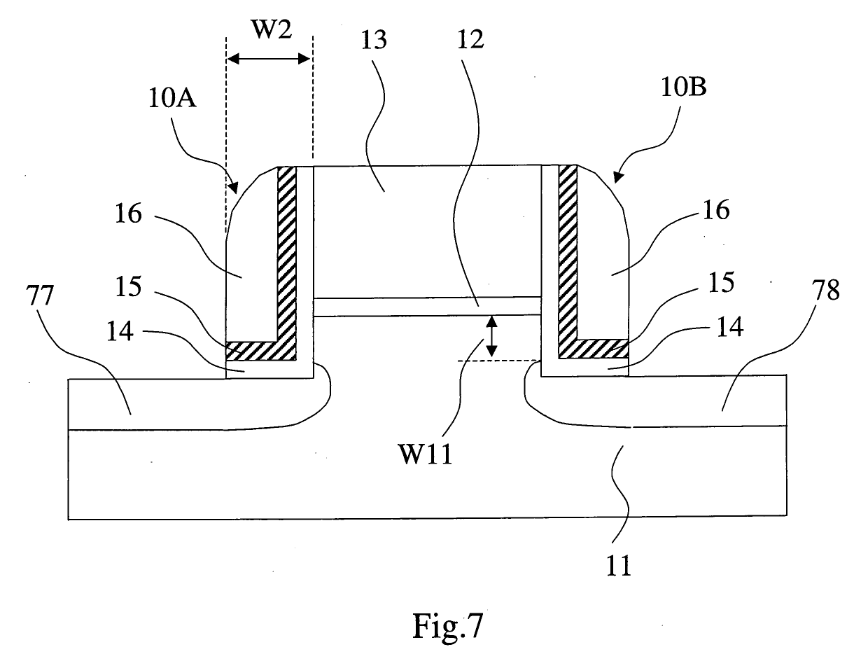

A memory cell that makes up a semiconductor memory according to a third embodiment of the invention is shown in FIG. 7. The memory cell has diffusion regions extended to vertical side surfaces of a protrusion below opposite edges of a gate electrode. The length W11 of offset regions is set to be shorter than the etching depth of a substrate 11. Therefore, a greater amount of current can be obtained compared to the current amount in the first and second embodiments.

The memory cell of this embodiment can be fabricated by the following steps. First and second diffusion regions 17, 18 shown in FIG. 5B are formed in completely the same manner as in the first embodiment. Then, the first and second diffusion regions 17, 18 are extended by a thermal process to form first and second diffusion regions 77, 78. Alternatively, after forming charge-retaining portions 10A, 10B shown in FIG. 5D, the first and second diffusion regions 17, 18 can be extended by a thermal process to form the first and second diffusion regions 77, 78.

Writing and reading of the semiconductor memory of the third embodiment can be done in the same manner as in the first embodiment.

### Fourth Embodiment

In the memory of the first embodiment shown in FIG. 4, as the thickness of the silicon oxide film 14 increases, more charges can be suppressed from being injected from the gate electrode 13 to the silicon nitride film 15 or more charges can be suppressed from being dissipated from the silicon nitride film 15 to the gate electrode 13. However, depending on the thickness of the silicon oxide film 14, electrons accelerated in the direction of the arrow 32 have difficulty passing through the silicon oxide film 14 to be injected into the silicon nitride film 15. This impairs the writing efficiency. A memory cell that makes up a semiconductor memory according to a fourth embodiment of the invention can be made by increasing, in the semiconductor memory of the first embodiment, the thickness of the silicon oxide film 14 only on the sidewalls of the gate electrode. By doing so, the charge injection from the gate electrode to the charge-retaining portions can be suppressed or the charge dissipation from the charge-retaining portions to the gate electrode can be suppressed.

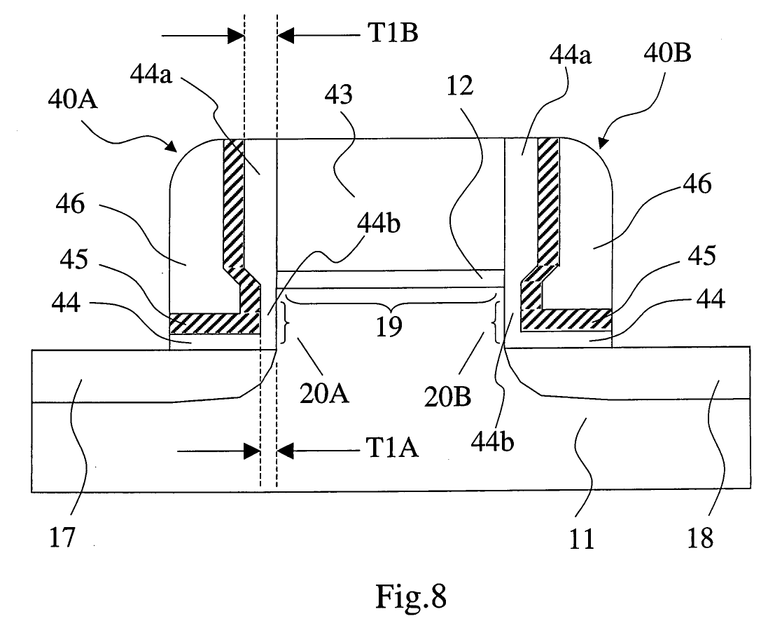

Now, the memory cell of the fourth embodiment is explained with reference to FIG. 8. In FIG. 8, the same reference numerals are assigned to the same members as those in the first embodiment. Differences from the first embodiment are described below. The memory cell of the fourth embodiment is characterized in that the thickness T1B of silicon oxide films 44 on sidewalls of a gate electrode 43 is greater than the thickness T1A of the silicon oxide films 44 on side surfaces of a protrusion of a semiconductor substrate 11. The side surfaces of the protrusion serve as offset regions 20A, 20B. In other words, a silicon oxide film 44a is formed to be thicker than a silicon oxide film 44b. This prevents a decrease in the writing efficiency. Furthermore, the charge injection from a gate electrode 43 to a silicon nitride film 45 or the charge dissipation from the silicon nitride film 45 to the gate electrode 43 can be effectively suppressed. Therefore, rewrite characteristics of the memory cell is stabilized, and its reliability is improved.

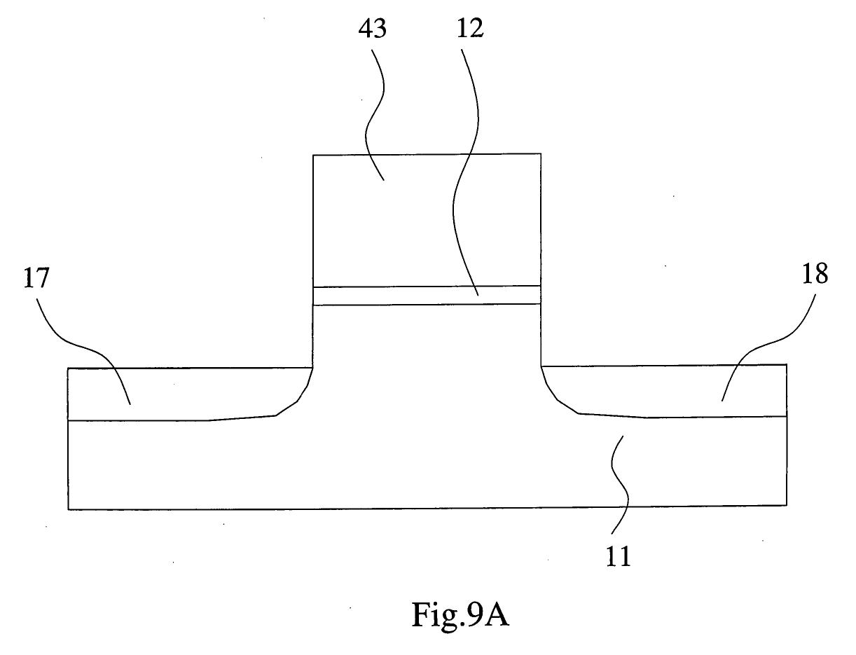

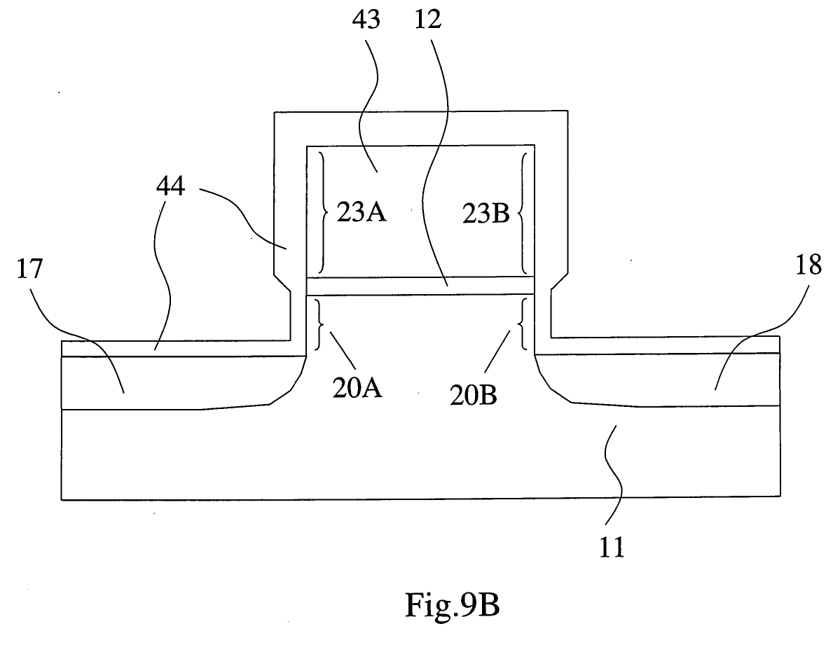

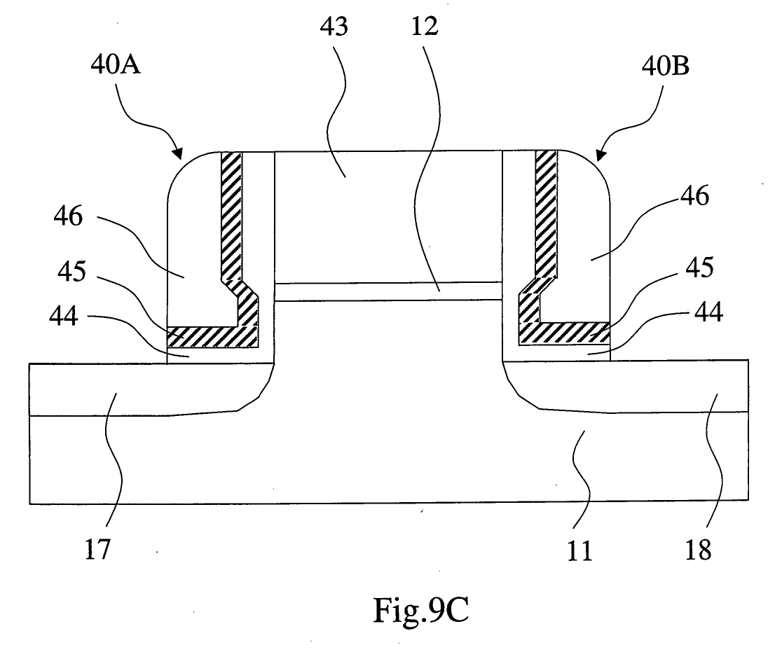

Steps of forming the memory cell of the fourth embodiment are now explained with reference to FIG. 9A to FIG. 9C. In the following example, a silicon substrate is employed as the semiconductor substrate and the gate electrode is made of polycrystalline silicon. First, on the semiconductor (silicon) substrate 11 in which isolation regions (not shown) are formed, a gate insulating film 12 and a gate electrode 43 of polycrystalline silicon are formed. Then, as shown in FIG. 9A, in the portions of the substrate on both sides of the protrusion, the diffusions regions 17, 18 are formed at a level below the upper surface of the protrusion in the same manner as used in the steps shown in FIG. 5A to FIG. 5D of the first embodiment.

Subsequently, as shown in FIG. 9B, the silicon oxide film 44 is formed on the surfaces of the substrate 11 and the gate electrode 43 by thermal oxidation. The thickness of the silicon oxide film 44 is greater on the sidewalls of the gate electrode 43 (regions 23A and 23B) than on the side surfaces of the protrusion (offset regions 20A, 20B). This is because the thermal oxidation rate of the gate electrode 43 made of polycrystalline silicon is greater than that of the substrate 11 made of monocrystalline silicon. Then, as shown in FIG. 9C, the memory cell is completed in the same manner as in the first embodiment.

In the memory of the fourth embodiment, the gate electrode is made of polycrystalline silicon, but the material of the gate electrode is not limited thereto. Any material that has a thermal oxidation rate greater than that of the substrate may be used. Where a silicon substrate is used as the semiconductor substrate, for example, a single-layer film or multilayer film of a metal such as copper, aluminum or the like; a refractory metal such as tungsten, titanium or the like; and/or a silicide of a refractory metal can be used.

According to the above steps, the thickness of the oxide film on the sidewalls of the gate electrode can be selectively increased without no additional steps, by using the difference in oxidation rate due to the crystallinity or material difference. Therefore, the highly reliable memory cell having stable rewrite characteristics can be fabricated in simple steps.

Writing and reading of the semiconductor memory of the fourth embodiment can be done in the same manner as in the first embodiment.

### Fifth Embodiment

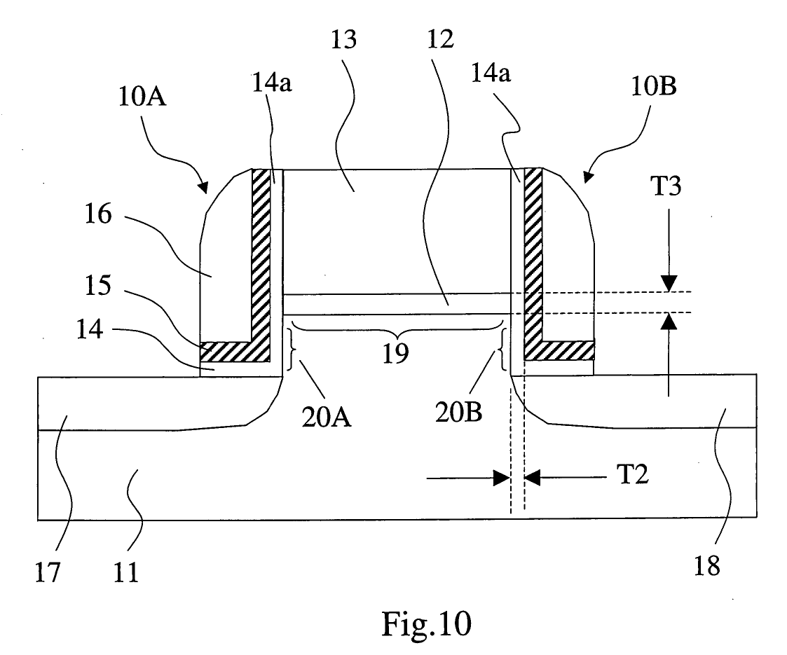

A memory cell that makes up a semiconductor memory according to a fifth embodiment of the invention is shown in FIG. 10. The memory cell is different from the memory of the first embodiment in that the thickness (T2) of a silicon oxide film 14a between a charge-retaining film (silicon nitride film 15) and a side surface of a protrusion is smaller than the thickness (T3) of a gate insulating film 12. The memory cells of the two embodiments are substantially the same except for the above.

There is a lower limit for the thickness T3 of the gate insulating film 12 due to a demand for high voltage operation of the memory during the rewriting thereof. However, the thickness T2 of the silicon oxide film 14a can be smaller than the thickness T3. By reducing the thickness T2, it is easier to inject charges into the charge-retaining portions. As a result of this, voltages applied for the writing and erasing operations can be lowered or the writing and erasing operations can be performed at a higher speed. Furthermore, the amount of charges induced to a channel region or well region while charges are accumulated in the silicon nitride film 15 is increased, and thereby the memory effect is improved.

Thus, by satisfying the relationship thickness T2<thickness T3, the high voltage operational property of the memory cell is not impaired. In addition to that, the writing and erasing voltages can be lowered or the writing and erasing operations can be done at a higher speed. Furthermore, the memory cell can have an increased memory effect.

Where the silicon oxide film 14 is used as the second insulating film as is in this embodiment, the thickness T2 of the insulating film is preferably 1.5 nm or greater as in the first embodiment. The thickness T2, however, can further be reduced by using as a material an insulating film other than the silicon oxide film. For example, the thickness T2 can be reduced when a high dielectric film such as of hafnium oxide, aluminum oxide or the like is used as the second insulating film, because when such a high dielectric film is used, an effective voltage applied to the second insulating film is more relaxed compared to when the silicon oxide film is used. Still, the thickness T2 of the insulating film is preferably 0.8 nm or greater, since this is a limit for and for preventing extreme degradation in retention characteristics. A fabrication process at this time needs to be maintained at a certain level so that the uniformity and quality of the film can be maintained at a certain level.

The semiconductor memory that is configured to satisfy the relationship of thickness T2<thickness T3 is suitable for devices that require low power consumption and low voltage operation.

Writing and reading of the semiconductor memory of the fifth embodiment can be done in the same manner as in the first embodiment.

### Sixth Embodiment

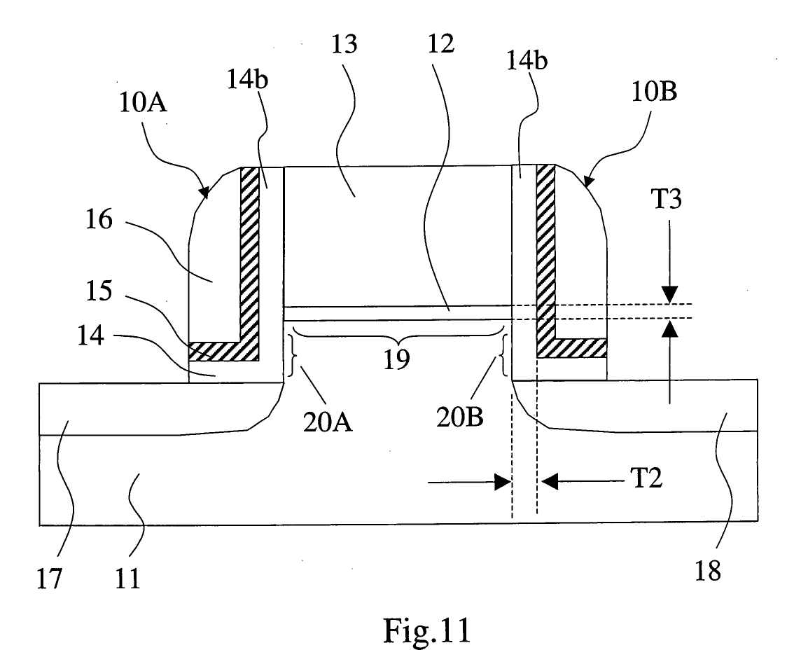

A memory cell that makes up a semiconductor memory according to a sixth embodiment of the invention is shown in FIG. 11. The memory cell of this embodiment is different from the memory of the first embodiment in that the thickness (T2) of a silicon oxide film 14b between a charge-retaining film (silicon nitride film 15) and a side surface of a protrusion is greater than the thickness (T3) of a gate insulating film 12. The memory cells of the two embodiments are substantially the same except for the above.

There is an upper limit for the thickness T3 of the gate insulating film 12 due to a demand for prevention of a short channel effect of the cell. However, the thickness T2 of the silicon oxide film 14b can be greater than the thickness T3. By making the thickness T2 greater than the thickness T3, charges accumulated in the charge-retaining portions can be prevented from being dissipated, and thus, the retention characteristics of the memory can be improved.

By thus satisfying the relationship thickness T2>thickness T3, it is possible to improve the retention characteristics of the memory without degrading the short channel effect of the memory.

The semiconductor memory that is configured to satisfy the relationship of thickness T2>thickness T3 is suitable for devices that require high charge retention characteristics, for example, devices that are used at a high temperature.

Where the silicon oxides film 14 is used as the second insulating film as is in this embodiment, the thickness T2 of the insulating film is preferably 15 nm or smaller as in the first embodiment. The thickness T2, however, can further be increased by using as a material an insulating film other than the silicon oxide film. For example, when a high dielectric film such as of hafnium oxide, aluminum oxide or the like is used as the second insulating film, the thickness T2 can be made thicker than when the silicon oxide film is used, without the electric field applied to the second insulating film being changed. Still, the thickness T2 of the insulating film is preferably 20 nm or smaller in view of the rewriting rate.

Writing and reading of the semiconductor memory of the sixth embodiment can be done in the same manner as in the first embodiment.

The semiconductor memories according to the first and sixth embodiments of the invention described hereinabove serve as memory cells that store quaternary or greater data by storing binary or greater data in one charge-retaining portion.

Furthermore, each of the memories of the invention is preferably formed on a semiconductor substrate, and more preferably on a well region of a first conductivity type formed in the semiconductor substrate. The substrate is not particularly limited and any substrate used in semiconductor devices may be used. For example, various substrates including substrates of elementary semiconductors such as silicon, germanium and the like and of compound semiconductors such as GaAs, InGaAs, ZnSe and the like, an SOI substrate and a multilayer SOI substrate may be used. Among those, a silicon substrate and an SOI substrate having a silicon layer formed thereon as a surface semiconductor layer are preferred. In the substrate, isolation regions are preferably formed. Components such as a transistor, capacitor, resistance and the like may further be formed, and circuits including such components may be formed. Furthermore, a semiconductor device or an interlayer insulating film may be combined to form a single or multilayer structure.

The isolation regions may be formed of any one of various isolation films such as a LOCOS film, trench oxide film, STI film and the like. The semiconductor substrate may have a P-type or N-type conductivity type. The substrate preferably has at least one well region of a first conductivity type (P-type or N-type). The substrate or the well region may have any impurity concentration that is in a range known in the art. Where the SOI substrate is used, the well region may be formed in the surface semiconductor layer and a body region may be provided below the channel region.

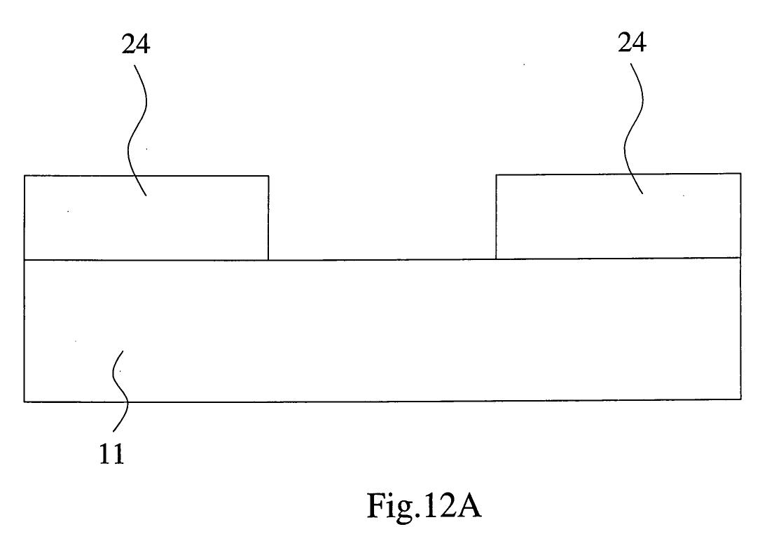

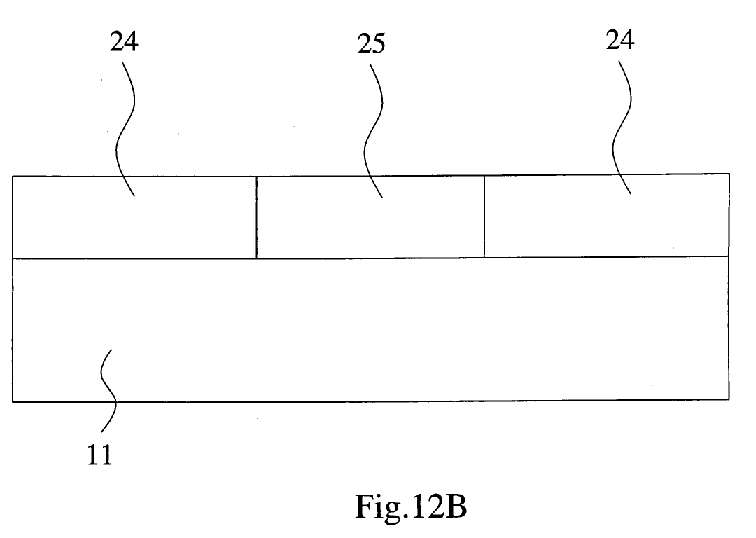

According to the semiconductor memories of the first to sixth embodiments of the invention, after the gate electrode is processed, it is used as a mask to form the protrusion of the substrate. However, the order of steps is not limited thereto, and the substrate having the protrusion may be formed prior to the formation of the gate electrode. For example, as shown in FIG. 12A, an oxide film 24 may be deposited on a silicon substrate 11 by a CVD method and processed into a desired shape. Then, as shown in FIG. 12B, an epitaxial silicon film 25 may be selectively grown in a region where the oxide film 24 is not formed, so that the silicon substrate 11 having the protrusion can be formed.

The gate insulating film is not particularly limited and any film that is usually used in semiconductor devices may be used. Examples of the gate insulating film include a single-layer or multilayer film of an insulating film such as a silicon oxide film, silicon nitride film, silicon oxide nitride film or the like, and/or a high dielectric film such as an aluminum oxide film, titanium oxide film, tantalum oxide film, hafnium oxide film or the like.

On the gate insulating film, the gate electrode is formed in a shape that is usually employed in semiconductor devices. The gate electrode is not particularly limited unless it is specifically defined in the embodiments. Examples of the gate electrode include a single-layer or multilayer film of polysilicon; a metal such as copper, aluminum or the like; a refractory metal such tungsten, titanium, tantalum or the like; and/or a silicide with the refractory metal. Suitably, the gate electrode is formed to have a thickness of, for example, about 50 nm to 400 nm.

The charge-retaining portions each includes a film or region having at least a function of retaining charges, a function of accumulating and retaining charges or a function of trapping charges. Examples of the film or region having such a function include: silicon nitride; silicon; silicate glass containing impurities such as phosphorus, boron or the like; silicon carbide; alumina; a high dielectric material such as hafnium oxide, zirconium oxide, tantalum oxide or the like; zinc oxide, a metal and the like.

Each charge-retaining portion may be formed of, for example, a single-layer or multilayer structure of an insulating film including a silicon nitride film; an insulating film including therein a dielectric film or semiconductor layer; and/or an insulating film including a dielectric material or at least one or more semiconductor dot. Among those, the silicon nitride film can obtain wide hysteresis characteristics because it has a number of levels that trap charges. The silicon nitride film also has excellent retention characteristics because it has a long charge retention time and does not cause a charge-leakage problem due to formation of a leak path. Furthermore, the silicon nitride film is preferred because it is a commonly used material in LSI processes.

The insulating film including therein an insulating film having a charge-retaining function, such as the silicon nitride film can have a higher reliability in terms of memory retention. Since the silicon nitride film is an insulator, even when a charge leakage occurs in a part of the film, charges are not immediately dissipated from the whole film. Even when the distance between a plurality of cells is shortened and adjacent cells come into contact, information stored in the respective charge-retaining portions is not lost as it is when the charge-retaining portions are formed of a conductive material. Further, a contact plug can be disposed close to the charge-retaining portions. In some cases, the contact plug may be disposed so as to overlap the charge-retaining portions, so that the shrinkage of the memory cells is easier.

In each charge-retaining portion, the insulator having the charge-retaining function is not necessarily in the form of a film in order to have a higher reliability in terms of memory retention. The insulator having the charge-retaining function may be discretely present in the insulating film. More specifically, a material which can hardly retain charges, for example, silicon oxide may contain the insulator scattered in dots.

The insulator having the charge-retaining function and the insulating film including therein the conductive film or semiconductor layer can be used as the charge-retaining portions. By doing so, the amount of charges injected to the insulator having the charge-retaining function, conductive film or semiconductor layer can be freely controlled. This not only allows for the multivalued charge-retaining portions but also improves an opportunity to retain the accumulated charges.

Thus, it is preferable that each charge-retaining portion further includes a region that interferes with the dissipation of charges or a film having a function of interfering with the dissipation of charges. Where the insulator having the charge-retaining function is in the form of a film, the charge-retaining portion preferably has a two-layer structure or more with the film having a function of interfering with charge dissipation. As such a film, a silicon oxide film or the like can be used.

The charge-retaining portions are formed on opposite sides of the gate electrode directly or via the insulating film. The charge-retaining portions are located directly above the semiconductor substrate (well region, body region, or source/drain regions or diffusion regions). The charge-retaining films on opposite sides of the gate electrode may be formed so as to entirely cover the sidewalls of the gate electrode directly or via the insulating film. However, only one charge-retaining film may be provided on at least one side surface of the protrusion.

Each charge-retaining portion preferably has a sandwich structure in which the first insulating film for accumulating charges is sandwiched between the second and third insulating films. Since the first insulator for accumulating charges is in the form of a film, the charge density of the first insulator can be increased in a short period of time by injection of charges, and a uniform charge density can be achieved. Where the charge distribution in the first insulator is not uniform, there is a possibility that the charges move inside the first insulator during the retention, which reduces the reliability of the memory cell. Where the charge-retaining portions each have the sandwich structure, high-speed rewriting of the semiconductor memory, improvement of reliability and securing of sufficient retention time would be possible.

Furthermore, where the accumulated charges are electrons, the first insulator is preferably greater in electron affinity than the second and third insulators. The electron affinity herein means an energy difference between a vacuum level and the lowest level of conduction electrons. Where the accumulated charges are holes, the energy difference between the vacuum level and the highest level of the valance band in the first insulator is preferably smaller than that in the second and third insulators. Where the aforementioned conditions are satisfied, charge dissipation from the film made of the first insulator that accumulates charges is effectively suppressed, and thereby the memory retention time is increased. Furthermore, the efficiency of injecting charges into the first insulator is increased so that the time required for rewriting is reduced.

The charge-retaining portions that satisfy the aforementioned conditions preferably each includes the first insulator of a silicon nitride film and the second and third insulators of silicon oxide films. The silicon nitride film can obtain wide hysteresis characteristics because it has a number of levels that trap charges.

Furthermore, the silicon oxide film and silicon nitride films are preferred because they are both materials commonly used in the LSI processes. Instead of silicon nitride, any one of hafnium oxide, tantalum oxide and yttrium oxide may be used as the first insulator. Instead of silicon oxide, the second third insulators may be aluminum oxide. The second and third insulators may be different materials or may be the same material.

The source/drain regions serve as the diffusion regions of an opposite conductivity type to the semiconductor substrate or the well region. Therefore, the source/drain regions are extended, on the channel side, to reach the edges of the protrusion and, on the opposite side, to reach the isolation regions. A junction between the source/drain region and the substrate or the well region preferably has an abrupt impurity concentration gradient, because hot electrons and hot holes are effectively generated at low voltages, allowing for high-speed operation at a lower voltage. The junction depth of the source/drain regions is not particularly limited and may be appropriately adjusted in accordance with the desired properties of the memory to be obtained. Where the SOI substrate is used, the source/drain regions may have a junction depth smaller than the thickness of the surface semiconductor layer. However, the source/drain regions preferably have a junction depth that is almost equal to the thickness of the surface semiconductor layer.

The invention thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor memory comprising:
a semiconductor substrate having a protrusion;
a gate insulating film formed on an upper surface of the protrusion;
a gate electrode formed on the gate insulating film;
diffusion regions formed in portions of the substrate on both sides of the protrusion, the diffusion regions being disposed so as to reach edges of side surfaces of the protrusion;
a channel region between the diffusion regions, the channel region being located below the gate electrode; and
a charge-retaining portion formed on at least one side surface of the protrusion.

2. The memory of claim 1, wherein the diffusion regions are formed so as to extend below opposite edges of the gate electrode.

3. The memory of claim 1, further comprising an isolation region for dividing the protrusion into a plurality of active regions, wherein an area of the substrate below the charge-retaining portion within the active region is a part of the diffusion regions

4. The memory of claim 1, wherein an amount of electric current that flows from one of the diffusion regions to the other diffusion region is changed depending on an amount of charges retained in the charge-retaining portion.

5. The memory of claim 1, wherein the charge-retaining potion includes a first insulator having a function of retaining charges, and second and third insulators having a function of preventing dissipation of the charges retained in the first insulator, the first insulator being sandwiched between the second and third insulators.

6. The memory of claim 5, wherein the first insulator is silicon nitride, and the second and third insulators are silicon oxide.

7. The memory of claim 6, wherein the second insulator is in the form of a film and is interposed between the substrate and the first insulator, the second insulator on the substrate has a thickness of 1.5 nm to 15 nm.

8. The memory of claim 5, wherein the first insulator above the substrate has a thickness of 2 nm to 15 nm.

9. The memory of claim 5, wherein the second insulator is in the form of a film and is interposed partially between the first insulator and the substrate and partially between the first insulator and a sidewall of the gate electrode, the second insulator on the sidewall of the gate electrode is greater in thickness than the second insulator on the side surface of the protrusion.

10. The memory of claim 5, wherein the second insulator on the side surface of the protrusion is smaller in thickness than the gate insulating film, the second insulator on the side surface of the protrusion having a thickness of 0.8 nm or greater.

11. The memory of claim 5, wherein the second insulator on the side surface of the protrusion is greater in thickness than the gate insulating film, the second insulator on the side surface of the protrusion having a thickness of 20 nm or smaller.

12. A method for fabricating a semiconductor memory comprising the steps of:
forming a gate insulating film on a semiconductor substrate;
forming a film, as a material of a gate electrode, on the gate insulating film, the material film being made of a material greater in thermal oxidation rate than the substrate;
forming the gate electrode by processing the material film;
forming a protrusion on a surface of the substrate by processing the substrate;
forming diffusion regions in the surface of the substrate; and
forming charge-retaining layers on side surfaces of the protrusion.

13. A method for fabricating a semiconductor memory comprising the steps of:
forming a gate insulating film on a semiconductor substrate;
forming a film, as a material of a gate electrode, on the gate insulating film, the material film being made of a material greater in thermal oxidation rate than the substrate;
forming the gate electrode by processing the material film;
forming a protrusion on a surface of the substrate by processing the substrate;
forming charge-retaining layers on side surfaces of the protrusion; and
forming diffusion regions in portions of the substrate below the charge-retaining layers.
